(19) United States
(12) Patent Application Publication
(10) Pub. No.: US 2024/0203802 A1
(43) Pub. Date: Jun. 20, 2024

(54) PACKAGE HOUSING

(71) Applicant: HUNAN SAN'AN SEMICONDUCTOR CO., LTD., Changsha (CN)

(72) Inventors: Ning YANG, Changsha (CN); Liule WANG, Changsha (CN); Hao CHEN, Changsha (CN)

(21) Appl. No.: 18/209,945

(22) Filed: Jun. 14, 2023

Related U.S. Application Data
(63) Continuation of application No. PCT/CN2023/088480, filed on Apr. 14, 2023.

(30) Foreign Application Priority Data
Dec. 15, 2022 (CN) 202211613694.7
Dec. 15, 2022 (CN) 202223370962.5
Dec. 15, 2022 (CN) 202223372840.X
Dec. 15, 2022 (CN) 202223373808.3

(51) Int. Cl. H01L 23/04

(52) U.S. Cl. CPC H01L 23/04; H01L 23/10

(57) ABSTRACT

A package housing is provided and includes: an outer frame, a cover, a heat dissipation bottom plate, and a fixing structure. The cover is connected to a side of the outer frame. The heat dissipation bottom plate is connected to the other side of the outer frame, wherein the heat dissipation bottom plate, the outer frame, and cover cooperatively define a receiving space, the outer frame has a connecting member disposed inside the receiving space, the connecting member is disposed between the heat dissipation bottom plate and the cover. The fixing structure is configured to connect the connecting member to the cover, wherein a part of the fixing structure located in the receiving space has an autographic projection on the connecting member, and the entire autographic projection locates on a surface of the connecting member near the cover.

### CROSS REFERENCE TO RELATED APPLICATIONS

The present application is a continuation-application of the international patent application No. PCT/CN2023/088480, filed on Apr. 14, 2023, which claims priorities of a Chinese patent application No. 202211613694.7, filed on Dec. 15, 2022, a Chinese patent application No. 202223372840.X, filed on Dec. 15, 2022, a Chinese patent application No. 202223370962.5, filed on Dec. 15, 2022, and a Chinese patent application No. 202223373808.3, filed on Dec. 15, 2022, and contents of which are incorporated herein by their entireties.

### TECHNICAL FIELD

The present disclosure relates to the field of packaging, and in particular to a package housing.

### BACKGROUND

A power module may generally be formed by packaging a power chip in a package housing. The package housing provides a basic mechanical structure for packaging the chip and provides mechanical support for the chip. An inside of the shell is enclosed, such that the chip received therein is protected from external physical damage, for example, the chip is prevented from directly contacting solid dust and liquids. Typically, an outer frame and a cover of the power module housing are physically connected to each other, allowing the cover to be fixed with the frame. In the art, the frame is arranged with a snap, and the cover defines a slot, such that the frame is fixed to the cover by fitting the snap with the slot. However, for the package housing in the art, the snap occupies a large amount of space inside the package housing, leaving less space available for receiving the chip.

### SUMMARY OF THE DISCLOSURE

The present disclosure provides a package housing, providing an increased amount of space inside the package housing for receiving the chip.

In a first aspect, the present disclosure provides a package housing, including: an outer frame, a cover, a heat dissipation bottom plate, and a fixing structure. The cover is connected to a side of the outer frame. The heat dissipation bottom plate is connected to the other side of the outer frame, wherein the heat dissipation bottom plate, the outer frame, and cover cooperatively define a receiving space, the outer frame has a connecting member disposed inside the receiving space, the connecting member is disposed between the heat dissipation bottom plate and the cover. The fixing structure is configured to connect the connecting member to the cover, wherein a part of the fixing structure located in the receiving space has an autographic projection on the connecting member, and the entire autographic projection locates on a surface of the connecting member near the cover.

In a second aspect, the present disclosure provides a package housing including: an outer frame, a cover, and a fixing structure. The cover is connected to a side of the outer frame, wherein the outer frame and cover cooperatively define a receiving space. The fixing structure is connected to the outer frame and the cover, wherein a part of the fixing structure located on a side of the cover facing towards the outer frame has an autographic projection on the outer frame, and the entire autographic projection locates on a surface of the outer frame near the cover.

### BRIEF DESCRIPTION OF THE DRAWINGS

FIG. 1 is a structural schematic view of a package housing according to an embodiment of the present disclosure.

FIG. 2 is an explosive view of the package housing shown in FIG. 1.

FIG. 3 is a top view of the outer frame of the package housing shown in FIG. 2.

FIG. 4 is a structural schematic view of a fixing structure of the package housing according to an embodiment of the present disclosure.

FIG. 5 is a schematic view of the fixing structure shown in FIG. 4 being engaged with the cover.

FIG. 6 is a structural schematic view of the fixing structure of the package housing according to an embodiment of the present disclosure.

FIG. 7 is a schematic view of the fixing structure shown in FIG. 6 being engaged with the cover.

FIG. 8 is a structural schematic view of the fixing structure of the package housing according to an embodiment of the present disclosure.

FIG. 9 is a cross sectional view of the fixing structure.

FIG. 10 is a cross sectional view of the structure shown in FIG. 3, taken along the line B-B.

FIG. 11 is an enlarged view of a portion V shown in FIG. 4.

FIG. 12 is a structural schematic view of connection between the snap and the fixing post shown in FIG. 3.

FIG. 13 is a structural schematic view of the outer frame and the heat dissipation bottom plate of the package housing according to an embodiment of the present disclosure.

FIG. 14 is a structural schematic view of the cover of the package housing shown in FIG. 13.

FIG. 15 is a cross sectional view of the first snap portion of the package housing shown in FIG. 13.

FIG. 16 is a structural schematic view of a first snap body of the first snap portion shown in FIG. 15.

FIG. 17 is an enlarged view of the portion D1 shown in FIG. 13.

FIG. 18 is a cross sectional view of the second snap portion of the power module package structure shown in FIG. 13.

FIG. 19 is a structural schematic view of a second snap body of the second snap portion shown in FIG. 7.

FIG. 20 is an enlarged view of the portion D2 shown in FIG. 13.

### DETAILED DESCRIPTION

Technical solutions in embodiments of the present disclosure will be clearly and completely described below by referring to the accompanying drawings of the embodiments of the present disclosure. Obviously, the embodiments described are only some of but not all of the embodiments of the present disclosure. All other embodiments obtained without creative work by any ordinary skilled person in the art, based on the embodiments in the present disclosure, shall fall within the scope of the present disclosure.

In the art, a power module may generally be formed by packaging a power chip in a package housing. The package housing includes an outer frame and a cover. While performing packaging, the cover is assembled with the outer frame encapsulate the chip in the package housing. While assembling the outer frame and the cover, the outer frame is arranged with a snap, and the cover defines a slot, and the outer frame is fixed with the cover through fitting the snap with the slot. A connecting member is further arranged inside the package housing to support the chip and to increase structural strength of the outer frame. In the art, the snap of the package housing is disposed in a direction where the connecting member faces an outer circumference of the outer frame. In this way, a space, which is inside the package housing and is defined in the direction where the connecting member faces an edge of the outer frame, may be occupied, mounting of the chip may be affected, and therefore, a power density of the power module is reduced. Moreover, the snap structure arranged in the art has insufficient connection strength and may be loosen easily. In order to improve the above technical problems, the present disclosure provides the following embodiments.

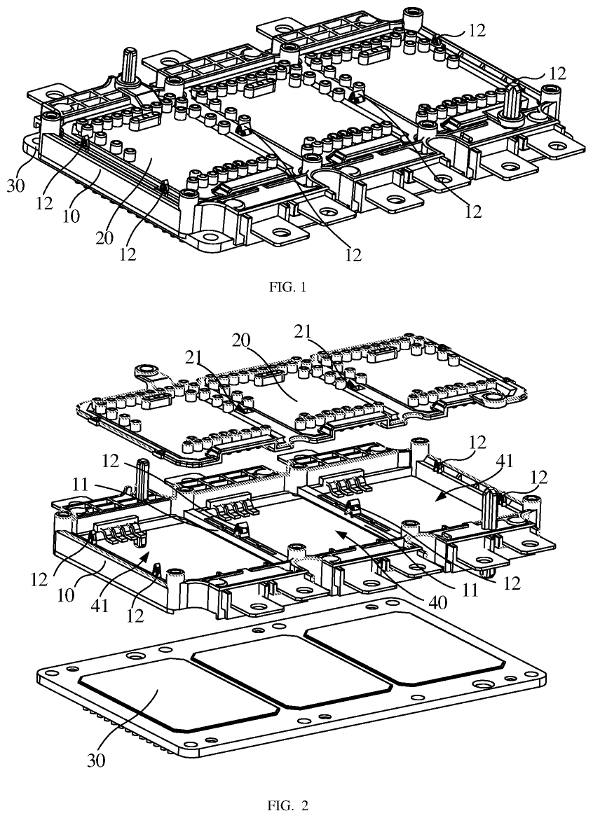

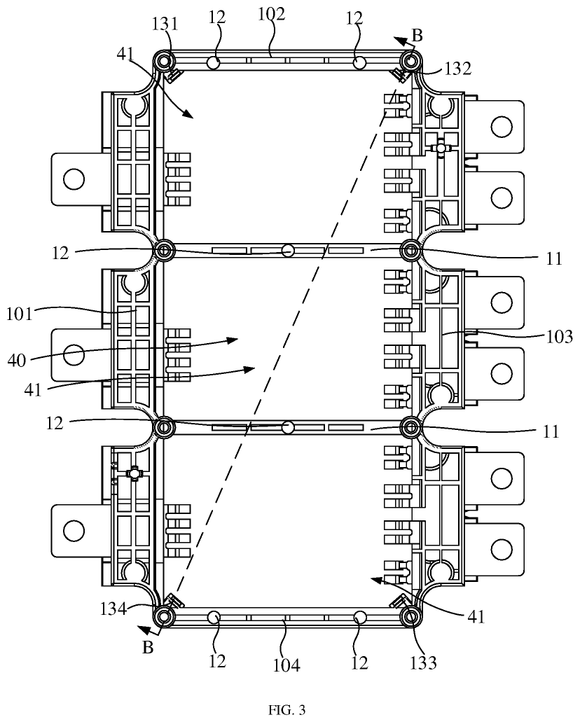

As shown in FIG. 1 and FIG. 2, the package housing 1 of the present disclosure includes an outer frame 10, a cover 20, and a heat dissipation bottom plate 30. The outer frame 10 serves as a basic structure of the package housing 1 and provides mounting positions and mechanical support for the cover 20, the heat dissipation bottom plate 30, and the chip, which will be mounted subsequently. The cover plate 20 and the heat dissipation bottom plate 30 are connected to two opposite sides of the outer frame 10. The cover 20 is connected to a side of the outer frame 10. The heat dissipation bottom plate 30 is connected to the other side of the outer frame 10. The heat dissipation bottom plate 30 may be connected to the outer frame 10 by screws, snaps or gluing, which will not be limited herein. The chip and wires may be arranged on the heat dissipation bottom plate 30. The heat dissipation bottom plate 30, the outer frame 10, and the cover 20 may be engaged with each other to cooperatively define a receiving space 40 in which the chip may be mounted.

As shown in FIG. 2, the outer frame 10 may be quadrilateral, hexagonal, and so on, which will not be limited herein. The chip may be arranged inside the outer frame 10. Pins may be arranged around the outer frame 10 to be electrically connected to the chip. A part of the pins arranged around the outer frame 10 may be located inside the outer frame 10, and the part inside the outer frame 10 may be electrically connected to the chip inside the package housing 1 after the packaging process. That is, the package housing 1 may further include the pins and the chip. Another part of the pins may be located at an outer periphery of the outer frame 10 and may be connected to other devices. The outer frame 10 further has a connecting member 11 received in the receiving space 40.

As shown in FIG. 3, in some embodiments, the outer frame 10 includes a first side 101, a second side 102, a third side 103, and a fourth side 104. The first side 101, the second side 102, the third side 103, and the fourth side 104 are arranged in sequence and are connected to each other end-to-end. The first side 101 is opposite to the third side 103, and the second side 102 is opposite to the fourth side 104.

The connecting member 11 is disposed between the heat dissipation bottom plate 30 and the cover 20. The connecting 11 is configured increase structural strength of the outer frame 10, allowing the outer frame 10 to be more firmed. The connecting member 11 is arranged with a fixing structure 12, and the fixing structure 12 is configured to connect the cover 20 with the connecting member 11 to fix the cover 20 to the outer frame 10.

An end of the connecting member 11 is connected to the first side 101 of the outer frame 10, and the other end of the connecting member 11 is connected to the third side 103 of the outer frame 10. In this way, a shape of the outer frame 10 may suitably match with a shape of the chip, and therefore, the package housing may be manufactured easily.

Specifically, a plurality of connecting members 11 are arranged inside the receiving space 40. The plurality of connecting members 11 are spaced apart from each other to separate the receiving space 40 into a plurality of receiving regions 41. Each of the plurality of receiving regions 41 may receive one chip. Each of the plurality of connecting members 11 may provide support for the chip.

The fixing structure 12 securely connects the connecting member 11 to the cover 20. While performing packaging, the cover 20 needs to be stably connected to the outer frame 10 to cooperatively define the receiving space 40 to receive the chip. The fixing structure 12 may easily and stably connect the connecting member 11 to the cover 20 to connect the cover 20 to the outer frame 10. As shown in FIG. 3, the part of the fixing structure 12 located inside the receiving space 40 has an autographic projection on the connecting member 11, and the entire autographic projection is located on a surface of the connecting member 11 near the cover 20.

In detail, in the art, the snap for fixing is protruding from a side of the connecting member 11 facing towards the edge of the outer frame 10, and therefore, the snap may occupy a part of the receiving region 41, such that a space for mounting the chip may be reduced, resulting in a reduction in a power density of the power module. Compared to related art, according to the relationship between the fixing structure 12 and the connecting member 11 in the present disclosure, the part of the fixing structure 12 located inside the receiving space 40 has the autographic projection on the connecting member 11, and the entire autographic projection is located on the surface of the connecting member 11 near the cover 20. In this way, on a plane where the cover 20 is located, the projection of the fixing structure 12 coincides with a projection of the connecting member 11. In the receiving space 40 and in a direction perpendicular to a thickness direction of the package housing 1, a space occupied by the fixing structure 12 coincides with a space occupied by the connecting member 11. Therefore, according to the present disclosure, the space occupied by the fixing structure 12 is reduced, allowing the space inside the package housing 1 for receiving the chip to be increased.

In some embodiments, as shown in FIG. 1 to FIG. 3, the package housing 1 includes the outer frame 10, the cover 20, and the fixing structure 12. The cover 20 is connected to a side of the outer frame 10, such that the outer frame 10 and the cover 20 cooperatively define the receiving space 40. The fixing structure 12 connects the outer frame 10 to the cover 20. A part of the fixing structure 12 located on the side of the cover 20 facing the outer frame 10 has the autographic projection on the outer frame 10, and the entire autographic projection locates on the surface of the outer frame 10 near the cover 20. That is, the fixing structure 12 may be disposed on both the first side 101 and the third side 103, or disposed on both the second side 102 and the fourth side 104 of the outer frame 10. In this way, fixation between the outer frame 10 and the cover 20 is further improved.

Specifically, in some embodiments, the fixing structure 12 may be disposed on each of a side of the first side 101 facing towards the cover 20 and a side of the third side 103 facing towards the cover 20. The part of the fixing structure 12 located on the side of the cover 20 facing the outer frame 10 has an autographic projection on the outer frame 10. The entire autographic projection of the fixing structure 12 disposed on the first side 101 locates on the surface of the first side 101 near the cover 20; and the entire autographic projection of the fixing structure 12 disposed on the third side 103 locates on the surface of the third side 103 near the cover 20.

Alternatively, in some embodiments, the fixing structure 12 may be disposed on each of a side of the second side 102 facing towards the cover 20 and a side of the fourth side 104 facing towards the cover 20. The part of the fixing structure 12 located on the side of the cover 20 facing the outer frame 10 has an autographic projection on the outer frame 10. The entire autographic projection of the fixing structure 12 disposed on the second side 102 locates on the surface of the second side 102 near the cover 20; and the entire autographic projection of the fixing structure 12 disposed on the fourth side 104 locates on the surface of the fourth side 104 near the cover 20.

The part of the fixing structure 12 located on the side of the cover 20 facing the outer frame 10 has an autographic projection on the outer frame 10, and the entire autographic projection locates on the surface of the outer frame 10 near the cover 20. In this way, on the plane where the cover 20 is located, the projection of the fixing structure 12 coincides with the projections of the first side 101 and the third side 103, or coincides with the projections of the second side 102 and the fourth side 104. Inside the receiving space 40 and in the direction perpendicular to the thickness direction of the package housing 1, the space occupied by the fixing structure 12 does not extend into the receiving space. In some embodiments, the fixing structure 12 may be provided on each of the outer frame 10 and the connecting member 11, such that fixation between the cover 20 and the outer frame 10 may be improved.

The fixing structure 12 will be exemplarily illustrated in the following.

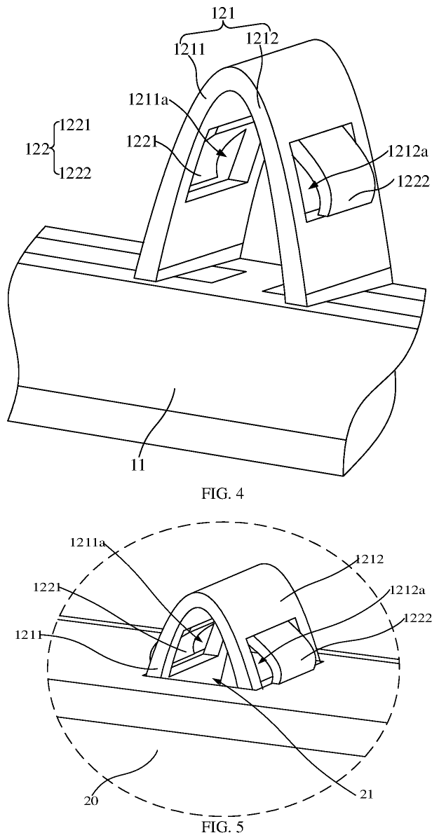

In some embodiments, as shown in FIG. 4 to FIG. 7, the fixing structure 12 includes a fixing portion 121 and a deformation portion 122. The fixing portion 121 is connected to the side of the connecting member 11 (or the outer frame 10, for illustration purposes only, the connecting member 11 will be used as an example hereinafter, as is the case when the fixing structure 12 is connected to the outer frame 10 and the cover 20) near the cover 20. The fixing portion 121 extends through a through hole 21. The deformation portion 122 is connected to the fixing portion 121. The deformation portion 122 is disposed on the side of the cover 20 away from the connecting member 11. The cover 20 defines the through hole 21. When performing assembling, the cover 20 is approaching the outer frame 10, and the fixing portion 121 passes through the through hole 21. The deformation portion 122 is deformed when being pressed by the cover 20. The deformation portion 122 and a part of the fixing portion 121 gradually pass through the through hole 21. After the deformation portion 122 passes through the through hole 21, the cover 20 does not press the deformation portion 122 any more, and the deformation portion 122 is restored. After the deformation portion 122 is restored, an end of the deformation portion 122 abuts against the cover 20, such that the end of the deformation portion 122 and the connecting member 11 cooperatively clamp the cover 20. In this way, the cover 20 is fixed to the outer frame 10 by fitting the fixing structure 12 with the through hole 21 in the cover 20.

The part of the fixing portion 121 located inside the receiving space 40 has an autographic projection onto the connecting member 11, and the autographic projection locates on the surface of the connecting member 11 near the cover 20. In this way, arranging the fixing portion 121 in the receiving space 40 does not occupy the receiving region 41, leaving more space inside of the package housing 1 for mounting the chip, such that the power density of the package module having the package housing 1 provided in the present disclosure may be increased.

As shown in FIG. 4 and FIG. 5, in some implementations of the above embodiments, specifically, the fixing portion 121 includes a first fixing plate 1211 and a second fixing plate 1212 opposite to the first fixing plate 1211. An end of the first fixing plate 1211 is connected to an end of the second fixing plate 1212. The other end of the first fixing plate 1211 and the other end of the second fixing plate 1212 are connected to the connecting member 11 and are spaced apart from each other. A connection position between the first fixing plate 1211 and the connecting member 11 is spaced apart from a connection position between the second fixing plate 1212 and the connecting member 11, such that an angle is formed between the first fixing plate 1211 and the second fixing plate 1212. In this way, a top of the fixing portion 121 may be narrow, and a bottom of the fixing portion 121 may be wide. While the fixing portion 121 is engaging with the through hole 21 of the cover 20, configuration of the fixing portion 121 may facilitate positioning of the through hole 21 with the fixing structure 12. In addition, the fixing portion 121 may guide the cover 20 to cap with the frame.

The deformation portion 122 includes a first deformation sub-portion 1221 and a second deformation sub-portion 1222. The first deformation sub-portion 1221 is connected to the first fixing plate 1211 and is extending towards the cover 20 to abut against the cover 20. Further, the first deformation sub-portion 1221 is extending away from the first fixing plate 1211. The second deformation sub-portion 1222 is connected to the second fixing plate 1212 and is extending towards the cover 20 to abut against the cover 20. Further, the second deformation sub-portion 1222 is extending away from the first fixing plate 1211.

The first deformation sub-portion 1221 is connected to a side of the first fixing plate 1211 away from the second fixing plate 1212. The second deformation sub-portion 1222 is connected to a side of the second fixing plate 1212 away from the first fixing plate 1211. A distance between an edge of the first deformation sub-portion 1221 away from the second fixing plate 1212 and an edge of the second deformation sub-portion 1222 away from the first fixing plate 1211 is greater than a width of the through hole 21. When the cover 20 is being assembled with the outer frame 10, the first deformation sub-portion 1221 and the second deformation sub-portion 1222 compressed by the cover 20 to be deformed to approach to each other, such that the first deformation sub-portion 1221 and the second deformation sub-portion 1222 may pass through the through hole 21. After the first deformation sub-portion 1221 and the second deformation sub-portion 1222 pass through the through hole 21, deformation of the first deformation sub-portion 1221 and the second deformation sub-portion 1222 are restored, and the first deformation sub-portion 1221 and the second deformation sub-portion 1222 abut against the cover 20. After the first deformation sub-portion 1221 and the second deformation sub-portion 1222 abut against the cover 20, and when the cover 20 tends to move away from the outer frame 10, the first deformation sub-portion 1221 and the second deformation sub-portion 1222 are deformed due to being compressed by the cover 20, and the first deformation sub-portion 1221 and the second deformation sub-portion 1222 are deformed in a direction away from each other. The first deformation sub-portion 1221 and the second deformation sub-portion 1222 cannot pass through the through hole 21 again. The first deformation sub-portion 1221 and the second deformation sub-portion 1222 apply a reaction force on the cover 20 to prevent the cover 20 from moving away from the outer frame 10. In this way, the outer frame 10 may be easily and stably connected to the cover 20 by the fixing structure 12. In some embodiments, the deformation direction of the first deformation portion 122 and the second deformation portion 122 is parallel to an extension direction of the connecting member 11. In this way, the first deformation portion 122 and the second deformation portion 122 may have reduced impact on the receiving region 41, and the chip may be mounted easily.

In some embodiments, the first fixing plate 1211 defines a first reservation hole 1211a at a position corresponding to the first deformation sub-portion 1221. The second fixing plate 1212 defines a second reservation hole 1212a at a position corresponding to the second deformation sub-portion 1222. The first deformation sub-portion 1221 is configured to be elastically bent towards the first fixing plate 1211. When the first deformation sub-portion 1221 is elastically deformed towards the first fixing plate 1211, the first deformation sub-portion 1221 may be received in the first reservation hole 1211a. The second deformation sub-portion 1222 is configured to be elastically bent towards the second fixing plate 1212. When the second deformation sub-portion 1222 is elastically deformed towards the second fixing plate 1212, the second deformation sub-portion 1222 may be received in the second reservation hole 1212a. In this way, the first deformation sub-portion 1221 and the second deformation sub-portion 1222 may be easily deformed by an action applied by the cover 20, such that the cover 20 may be easily assembled. In addition, the first reservation hole 1211a, the second reservation hole 1212a, the first deformation sub-portion 1221, and the second deformation sub-portion 1222 may be manufactured by a stamping process, such that the first deformation sub-portion 1221 and the first reservation hole 1211a, as well as the second deformation sub-portion 1222 and the second reservation hole 1212a, can be formed simultaneously in one stamping process. In this way, the fixing structure 12 may be easily manufactured.

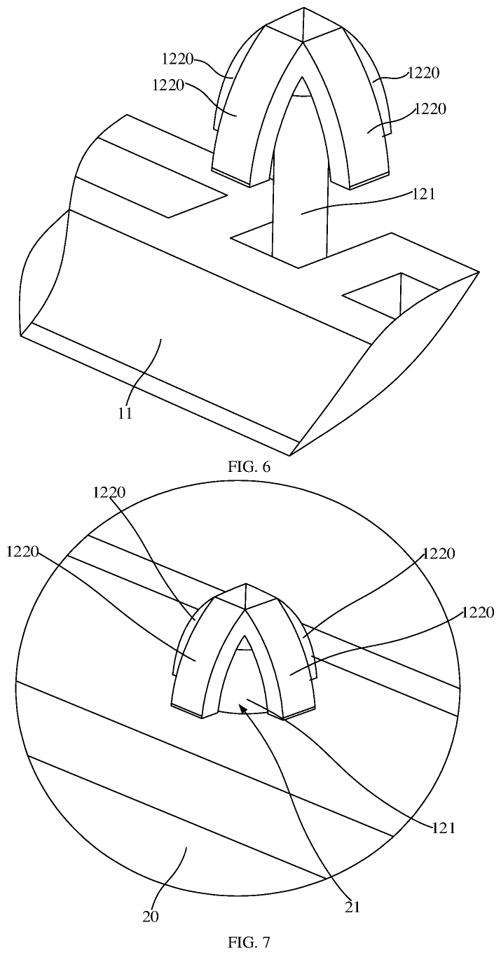

As shown in FIG. 6 and FIG. 7, in some implementations of the above embodiments, the deformation portion 122 includes a plurality of deformation sub-portions 1220. Each of the plurality of deformation sub-portions 1220 is connected to the fixing portion 121. Each deformation sub-portion 1220 is extending towards the cover 20 to abut against the cover 20. Each of the plurality of deformation sub-portions 1220 is extending away from the fixing portion 121. Specifically, the fixing portion 121 is column shaped. An end of each deformation sub-portion 1220 is connected to an end of the fixing portion 121 away from the connecting member 11, and the other end of each deformation sub-portion 1220 is extending in a direction approaching the cover 20 and away from the fixing portion 121. In this way, while the cover 20 is being assembled, the deformation sub-portions 1220 are deformed by the cover 20 in a direction approaching the fixing portion 121, such that the sub-deformation sub-portions 1220 may pass through the through hole 21. After the deformation sub-portions 1220 pass through the through hole 21, the deformation is restored, and the deformation sub-portions abut against the cover 20. After the deformation sub-portions 1220 abut against the cover 20, and when the cover 20 tends to move away from the outer frame 10, the deformation sub-portions 1220 are deformed by pressure generated by the cover 20. The deformation sub-portions 1220 are deformed in a direction away from the fixing portion 121. The deformed sub-portions 1220 cannot pass through the through hole 21 again. The deformed sub-portions 1220 generate a reaction force on the cover 20 to prevent the cover 20 from moving away from the outer frame 10. In this way, the outer frame 10 may be easily and stably connected to the cover 20 by the fixing structure 12.

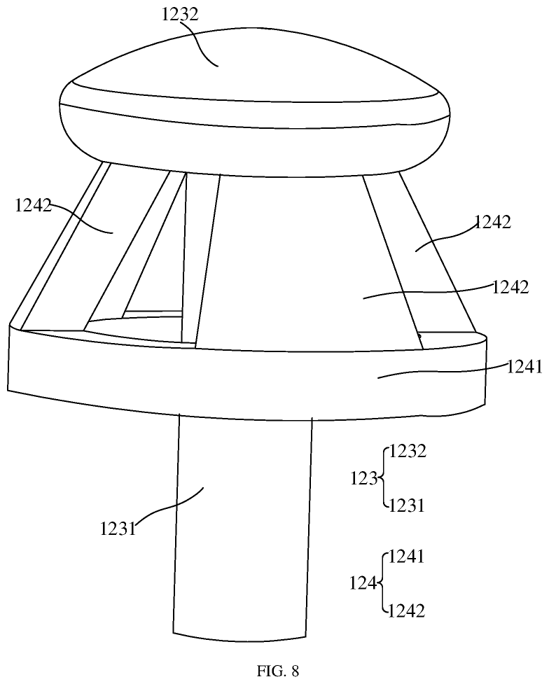

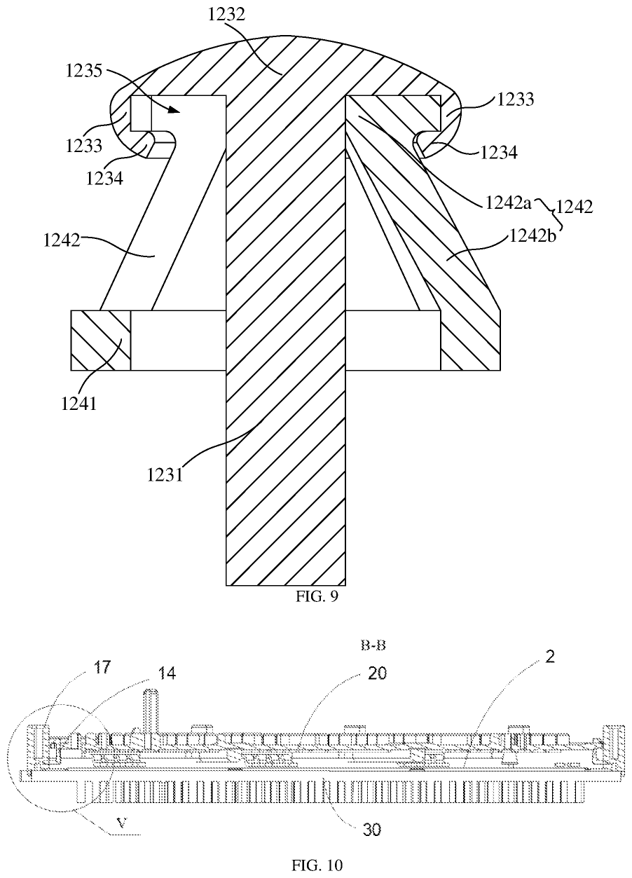

As shown in FIG. 8 and FIG. 9, in another embodiment, the fixing structure 12 includes a first snap portion 123 and a second snap portion 124. The first snap portion 123 is connected to the side of the connecting member 11 near the cover 20. The cover 20 defines the through hole 21 (see FIG. 2). The first snap portion 123 extends through the through hole 21. A part of the first snap portion 123 located inside the receiving space 40 has an autographic projection on the connecting member 11, and the autographic projection locates on the surface of the connecting member 11 near the cover 20. In this way, the part of the first snap portion 123 located inside the receiving space 40 does not additionally occupy the receiving region 41, such that a space inside the package housing 1 is left for mounting the chip, and the power density of the package module having the package housing 1 provided in the present disclosure may be increased. The second snap portion 124 snaps with the first fixing portion 121 and is disposed at a side of the cover away from the connecting member 11, such that the second snap portion 124 and the connecting member 11 cooperatively clamp and fix the cover 20. Engagement between the first snap portion 123 and the second snap portion 124 may fix the cover 20 to the outer frame 10 more firmly.

In detail, the first snap portion 123 includes a flange portion 1232 and a rod portion 1231. An end of the rod portion 1231 is connected to the connecting member 11, and the other end of the rod portion 1231 is connected to a middle of the flange portion 1232. A part of the rod portion 1231 located inside the receiving space 40 has an autographic projection on the connecting member 11, and the autographic projection locates on the surface of the connecting member 11 near the cover 20. The second snap portion 124 includes a mounting portion 1241 and a plurality of elastic portions 1242. The mounting portion 1241 is disposed on a side of the cover 20 away from the connecting member 11. The plurality of elastic portions 1242 are arranged on the mounting portion 1241 and are disposed around an outer circumference of the rod portion 1231. An end of each of the plurality of elastic portions 1242 is connected to the mounting portion 1241. Each of the plurality of elastic portions is extending towards the through hole 21 to abut against the flange portion 1232. Further, each of the plurality of elastic portions 1242 is extending away from the cover 20. The mounting portion 1241 and the cover 20 may be configured as a one-piece integral structure, or the mounting portion 1241 may be configured to be separated from the cover 20, which will not be limited herein.

Engagement between the first snap portion 123 and the second snap portion 124 are as follows. When the cover 20 is being assembled, the first snap portion 123 passes through the through hole to contact the plurality of elastic portions 1242. Due to the pressure generated by the cover 20, the flange portion 1232 in the first snap portion 123 compresses the plurality of elastic portions 1242 to deform the plurality of elastic portions 1242. The plurality of elastic portions 1242 move in a direction away from the flange portion 1232 and the rod portion 1231. The distance between the plurality of elastic portions 1242 is increased, and the flange portion 1232 is able to pass through a space defined by the plurality of elastic portions 1242. After the flange portion 1232 reaches a position higher than an upper end of the elastic portions 1242, the plurality of elastic portions 1242 are elastically restored. The plurality of elastic portions 1242 move to approach the rod portion 1231. In this way, the cover 20 is assembled in place. When the cover 20 tends to move away from the outer frame 10, the mounting portion 1241 drives the elastic portions 1242 to apply a pressure to the flange portion 1232. Since the elastic portions 1242 tilts towards the rod portion 1231, the elastic portions 1242 are deformed towards the rod portion 1231 when receiving the reaction force applied by the flange portion 1232. The distance between the plurality of elastic portions 1242 tends to be decreased, such that the flange portion 1232 is unable to pass through the space defined by the plurality of elastic portions 1242. Therefore, the cover 20 may be stably assembled to the outer frame 10 by the first snap portion 123 and the second snap portion 124.

In some embodiments, the first snap portion 123 further includes a first extension portion 1233 and a second extension portion 1234. The first extension portion 1233 extends from a circumference of the flange portion 1232 towards the rod portion 1231. The second extension portion 1234 extends from a circumferential side of the first extension portion 1233 near the rod portion 1231 away from the cover 20. The first extension portion 1233, the second extension portion 1234, the flange portion 1232, and the rod portion 1231 cooperatively define an embedding slot 1235. Each of the plurality of elastic portions 1242 includes an embedding portion 1242a and a connecting portion 1242b. An end of the connecting portion 1242b is connected to the mounting portion 1241 and is extending to approach the through hole 21 to abut against the flange portion 1232 and the first extension portion 1233. Further, the connecting portion 1242b is extending away from the cover 20. The embedding portion 1242a is connected to the end of the connecting portion 1242b away from the cover 20 and is received in the embedding slot 1235 to be snapped with the first extension portion 1233 and the second extension portion 1234. Snapping the embedding portion 1242a with the embedding slot 1235 allows the first snap portion 123 to be engaged with the second snap portion 124 more stably, such that the cover 20 may be engaged with the outer frame 10 more stably.

As shown in FIG. 3, for example, in some embodiments, the outer frame 10 has a first snap member 131, a second snap member 132, a third snap member 133, and a fourth snap member 134. The first snap member 131 is disposed near the connection between the first side 101 and the second side 102. The second snap member 132 is disposed near the connection between the second side 102 and the third side 103. The third snap member 133 is disposed near the connection between the third side 103 and the fourth side 104. The fourth snap member 134 is disposed near the connection between the fourth side 104 and the first side 101. The first snap member 131, the second snap member 132, the third snap member 133, and the fourth snap member 134 are each snapped with the cover 20. In this way, four corners and four edges of the cover 20 may be fixed to the outer frame 10 by the first snap member 131, the second snap member 132, the third snap member 133, and the fourth snap member 134. The fixing structure 12 secures a central part of the cover 20 to the connecting member 11. The first snap member 131, the second snap member 132, the third snap member 133, the fourth snap member 134, and the fixing structure 12 cooperatively connects the cover 20 to the outer frame 10 stably. In this way, connection strength of the package housing 1 is improved, and the cover 20 may not be loosen relative to the outer frame 10 easily.

In some embodiments, as shown in FIG. 9 to FIG. 12, the present embodiment provides a package housing 1 having high connection strength that enhances assembly stability of the cover, the cover may not be easily loosened, and an impact in a usage area inside of the cover may be reduced, a packaging space inside the cover may be increased, such that the power module may be miniaturized.

The package housing 1 provided in the preset embodiment may be applicable for the power module. The package housing 1 includes the outer frame 10 and the cover 20. The cover 20 is snapped with the outer frame 10 and is arranged inside the outer frame 10. Further, an apex of an inner corner of the outer frame 10 is arranged with the snap 14. The snapping slot 22 is defined correspondingly in the cover 20. The snap 14 is snapped with the snapping slot 22.

In some embodiments, the package housing 1 is applicable for the power module. The outer frame 10 may be fixed to a heat dissipation bottom plate 30 by a sealing adhesive such as silicone. Further, the heat dissipation bottom plate 30 is further attached with a chip 2. The outer frame 10 surrounds the chip 2. In this way, a packaging structure of the heat dissipation bottom plate 30 is provided for packaging the module, and a mechanical support is provided for the module, such that a complete package structure of the power module is formed. The cover 20 is snapped to the inside of the outer frame 10 and caps an outside of the chip 2, such that enclosure is provided, and the chip 2 inside the enclosure is prevented from being subjected to an external physical damage, for example, the chip may be prevented from directly contacting solid dust or liquid.

While performing assembly in practice, the chip 2 may be attached firstly, the outer frame 10 may be glued subsequently, and finally, the cover 20 may be snapped. The snap 14 is disposed at the apex of the inner corner of the outer frame 10, and the cover 20 defines the snapping slot 22 correspondingly. The snap 14 snaps with the snapping slot 22. In this way, the cover 20 snapping and fixing with the outer frame 10 may be achieved. After the snap 14 is assembled with the snapping slot 22, two sides of the cover 20 may be limited at the same time, such that stability of the assembling may be improved, the assembled structure may not be loosened easily. Moreover, the snap 14 is disposed at the apex of the inner corner, and therefore, a usage area of the cover 20 and an inner substrate may not be affected, such that the usage area of the cover 20 and the inner substrate may be increased.

To be noted that, in some implementations, the cover 20 has a plurality of regions, and each of the plurality of regions corresponds to one chip 2, allowing a plurality of chips 2 to be integrally packaged and improving the integration of the package. For example, in some embodiments, the cover 20 has 3 regions corresponding to 3 chips 2, respectively. That is, the heat dissipation bottom plate 30 is attached with 3 chips 2, and the 3 chips 2 are all disposed inside the outer frame 10.

To be noted that, in some embodiments, the outer frame 10 may be polygonal. In this case, the apex of the inner corner of the outer frame 10 refers to an apex of an inner corner formed by two adjacent edges. The shape of the cover 20 is adapted to the shape of the outer frame 10. The snap 14 is arranged at the apex of the inner corner, and the corresponding snapping slot 22 is defined in the cover 20. Therefore, after the snap 14 is assembled with the snapping slot 22, the adjacent edges of the cover 20 may be limited simultaneously by the snap 14, such that stability of the assembly may be improved.

The outer frame 10 includes a plurality of sides (such as, the first side 101, the second side 102, the third side 103, and the fourth side 104 in FIG. 3). The plurality of sides are connected with each other end-to-end. A fixing post 17 is arranged at the connection between two adjacent sides. The snap 14 is arranged on the fixing post 17. Specifically, the outer frame 10 may be polygonal in shape, and a plurality of sides of the polygonal shape are connected with each other end-to-end to form a closed polygonal frame to protect the chip 2 disposed therein. The fixing post 17 is connected to two adjacent sides at the same time to strengthen an overall frame structure. In addition, the fixing post 17 defines a mounting hole, enabling the fixing post to be connected to other components of the power module.

In some embodiments, the outer frame 10 is rectangular in shape, and an apex of each of four inner corners of the rectangular frame is arranged with one snap 14. Specifically, the outer frame 10 includes four sides, two of the four sides are opposite to each other, and the rest two of the four sides are opposite to each other. Two adjacent sides are perpendicular to each other. In addition, the fixing post 17 may be cylindrical and may be disposed at the apex of each of the four inner corners. The cover 20 may also be a rectangular plate and assembled with the outer frame 10. The snap 14 are disposed at the apex of each of the four inner corners, and the snapping slot 22 is defined at an apex of each of four top corners of the cover 20, such that the cover 20 is limited by snapping with the four top corners of the cover 20.

In some embodiments, the shape of the cover 20 is adapted to the shape of the outer frame 10. The snapping slot 22 is defined at each of the four top corners of the cover 20. The snapping slot 22 extends through the cover 20. Therefore, a part of the snap 14 may extend out of the snapping slot 22 to snap to the surface of the cover 20. The snapping slot 22 may be rectangular, enabling the snap 14 to extend out of the snapping slot 22 easily. Further, an arrangement direction of the snapping slot 22 is adapted to an arrangement direction of the snap 14 to ensure the snap 14 to fit exactly in the snapping slot 22, such that the snap 14 may be prevented from twisting to generate a large torque.

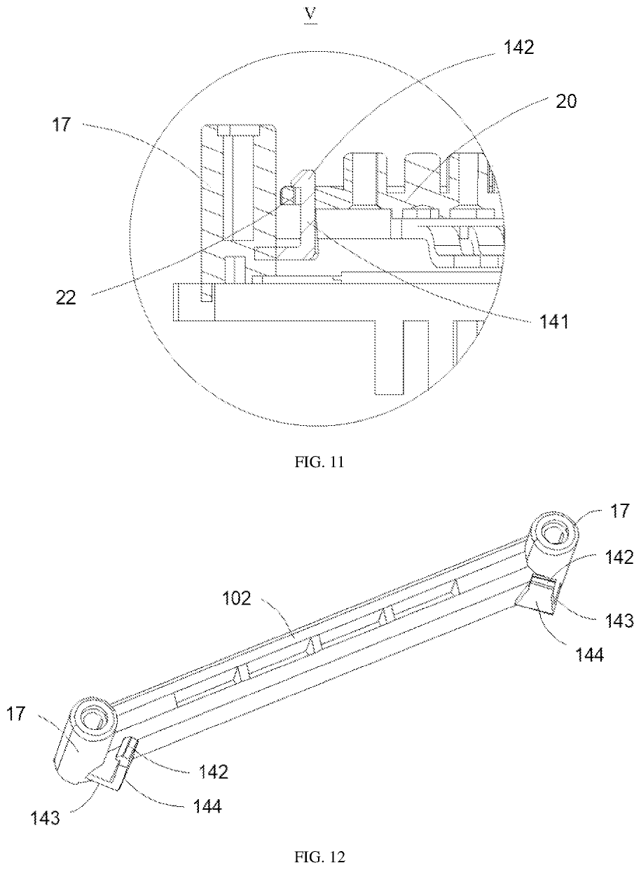

As shown in FIG. 11 and FIG. 12, the snap 14 includes an elastic connection base 141 and a snap hook 142, and the elastic connection base 141 and the snap hook 142 are configured as a once-piece integral structure. The elastic connection base 141 is connected to an inner side of the fixing post 17. The snap hook 142 is disposed at an end of the elastic connection base 141 and protrudes towards the fixing post 17. The elastic connection base 141 may be suspended at the inner side of the fixing post 17, extend towards a center of the outer frame 10 for a short distance and may be further bent upwards. In this way, the elastic connection base 141 has a certain elasticity. The snap hook 142 is integrally disposed at a top of the elastic connection base 141, and the elastic connection base 141 and the snap hook 142 are configured as the once-piece integral structure. Further, the snap hook 142 protrudes in a direction away from the center of the outer frame 10. A size of the snapping slot 22 in the cover 20 is adapted to a size of the snap hook 142, such that the snap hook 142 may pass through the snapping slot 22 to further abut against the surface of the cover 20, ensuring a snapping effect of the snap 14.

In some embodiments, two snap hooks 142, which correspond to two fixing posts 17 located on a diagonal, are protruding in opposite directions. Specifically, the two snap hooks 142 located on the diagonal are both protruding in the direction away from the center of the outer frame 10. Therefore, the two snap hooks 142 are protruding in opposite directions. When the snap 14 is being assembled with the snapping slot 22, the two hooks 142, which are protruding in opposite directions, may abut against the cover 20 in opposite directions, such that a better fixing effect may be achieved. While performing assembling in practice, when the cover 20 and the outer frame 10 are assembled with each other by the snap 14, the elastic connection base 141 may be deformed to some a certain extent, and the assembling may be achieved only when the deformation is generated. Further, the deformed elastic force is opposite to the elastic force of the snaps 14 disposed at the diagonal, such that an interactive force is formed, and the cover 20 may be abutted in the diagonal direction, and therefore, the fixing effect is enhanced. In addition, during vibration, when one of the snaps 14 disposed at the diagonal tends to be released from binding, the other one of the snaps 14 disposed at the diagonal may strengthen the binding, such that the fixing may be enhanced eventually.

To be noted, that the outer frame 10 is a rectangular frame. Therefore, the diagonal refers to a diagonal of the rectangle. When the outer frame 10 is in another polygonal shape, such as a pentagonal or hexagonal shape, the diagonal refers to a line connecting two apexes of two inner corners that are not adjacent to each other.

In some embodiments, the size of the snapping slot 22 is slightly greater than a size of the snap hook 142, and a cross-sectional shape of the snap hook 142 is adapted to the shape of the snapping slot 22, enabling the snap hook 142 to extend out of the snapping slot 22 from the bottom to the up. When the snap hook is snapped in place, the snap hook 142 may extend out of the snapping slot 22 to abut against and snap with the surface of the cover 20, and a part of the elastic connection base 141 is received in the snapping slot 22, such that positioning may be achieved, and elasticity may be provided to the snap hook 142.

In some embodiments, the elastic connection base 141 includes a connecting portion 143 and an elastic portion 144. An end of the connecting portion 143 is arranged on the inner side of the fixing post 17, and the other end of the connecting portion 143 extends away from the fixing post 17. An end of the elastic portion 144 is connected to the end of the connecting portion 143 away from the fixing post 17, and the elastic portion 144 is bent with respect to the connecting portion 143. The snap hook 142 is disposed at an end of the elastic portion 144 away from the connecting portion 143. Specifically, the connecting portion 143 and the elastic portion 144 are configured as a one-piece and integral structure, and are both sheet-shaped. The connecting portion 143 is configured to achieve connection, and the elastic portion 144 is configured to support the snap hook 142 and provide an elastic force.

In some embodiments, the elastic portion 144 is tilted with respect to the connecting portion 143 towards the fixing post 17. Specifically, the connecting portion 143 is disposed in the horizontal direction, and the elastic portion 144 is tilted in a direction away from the center of the outer frame 10. Therefore, the elastic portion 144 provides a certain preloading force, such that, after the snap 14 is assembled with the snapping slot 22, the snap hook 142 may firmly abut against the cover 20 due to the preloading force.

In some embodiments, an angle between the protruding direction of the snap hook 142 and the extension direction of the frame side is between 40° and 60°. When the angle between the protruding direction of the snap hook 142 and the extension direction of the frame side is 45°, a better elastic support may be achieved, and snapping may be achieved easily.

In some embodiments, a width of the elastic portion 144 decreases gradually in a direction away from the connecting portion 143. Specifically, a width of a top of the elastic portion 144 is the same as a width of the snap hook 142, and a width of a bottom of the elastic portion 144 is the same as a width of the connecting portion 143, such that the entire snap 14 has a narrow top and a wide bottom. The connecting portion 143 is connected to the fixing post 17 and has a larger width, such that mechanical strength of the snap 14 itself may be improved. Since the snap hook 142 and the top of the elastic portion 144 have small widths, the snap hook 142 and the elastic portion 144 may occupy a reduced space and may be snapped with the snapping slot 22, facilitating assembly.

As shown in FIG. 10, in another aspect, the present embodiment further provides a power module including the chip 2, the heat dissipation bottom plate 30, and the above-mentioned package housing 1. The chip 2 is mounted on and attached to the heat dissipation bottom plate 30 and is disposed inside the outer frame 10. The cover 20 covers the chip 2. In this way, a complete power package structure is formed. The outer frame 10 may be fixedly adhered to the heat dissipation bottom plate 30 by a sealing adhesive, such as silicone. In addition, the heat dissipation bottom plate 30 is attached with the chip 2. The outer frame 10 surrounds the chip 2. In this way, a packaging structure of the heat dissipation bottom plate 30 is provided for packaging the power module, and a mechanical support is provided for the module. The cover 20 is snap with the outer frame 10 and is disposed inside of the outer frame 10, and covers the outside of the chip 2. In this way, a closure is provided, preventing the chip 2 disposed therein from being subject to any external physical damage, for example, the chip 2 may be prevented from directly contacting solid dust or liquid. While performing assembling in practice, the chip 2 may be attached to the heat dissipation bottom plate 30 firstly, the outer frame 10 is adhered to the heat dissipation bottom plate 30 subsequently, and finally, the cover 20 is snapped.

To summarize, for the package housing 1 and the power module in the present embodiments, the cover 20 is disposed inside the outer frame 10, the snap 14 is disposed at the apex of the inner corner of the outer frame 10, the cover defines the snapping slot 22 correspondingly, and the snap 14 is snapped with the snapping slot 22, such that the cover 20 is snapped with and fixed to the outer frame 10. Compared to the related art, in the present disclosure, the snap 14 is disposed at the apex of the inner corner of the outer frame 10. After the snap 14 is snapped with the snapping slot 22 are assembled, two sides of the cover 20 can be limited at the same time, such that stability of the assembling is enhanced, and the assembled structure may not be loosened easily. Moreover, since the snap 14 is disposed at the apex of the inner corner, the usage area of the cover 20 and the internal substrate may not be affected, increasing the usage area of the cover 20 and the internal substrate.

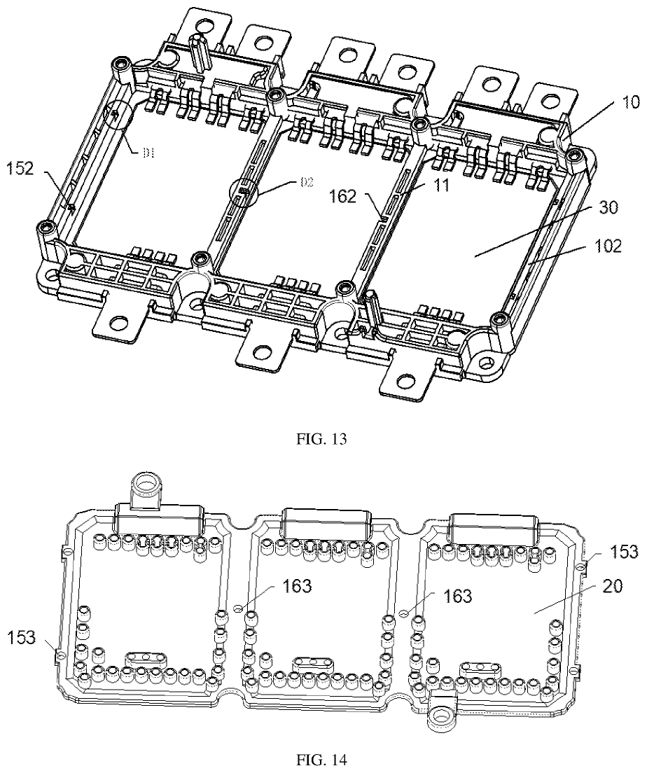

In some embodiments, as shown in FIG. 13 to FIG. 15, FIG. 13 shows a frame and the substrate of the package housing 1; and FIG. 14 shows the cover of the package housing 1 shown in FIG. 1. In the present embodiment, the package housing 1 includes the heat dissipation bottom plate 30, the outer frame 10 fixedly arranged on the heat dissipation bottom plate 30, and a cover plate 20 disposed on a side of the outer frame 10 away from the heat dissipation bottom plate 30. The outer frame 10 includes an outer side frame, and the outer side frame is configured to define a region for mounting the power chip.

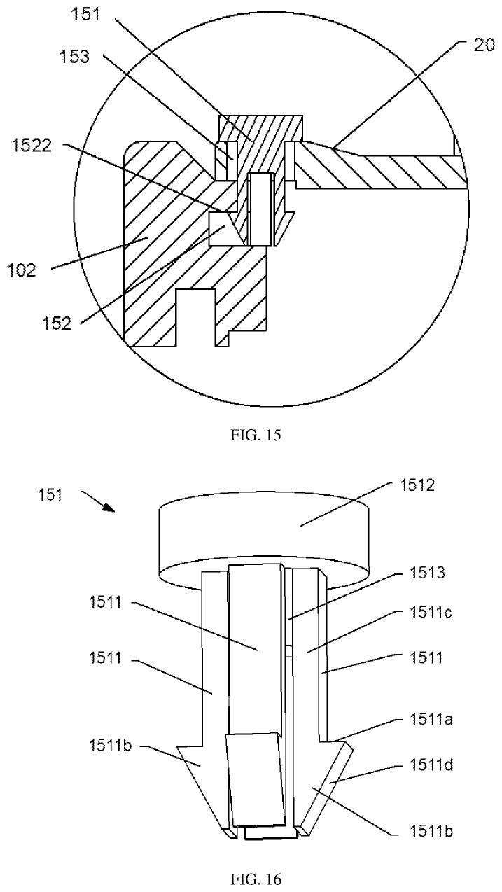

As shown in FIG. 13 and FIG. 15, the package housing 1 further includes a first snap portion 15. The first snap portion 15 includes a first snap body 151, a first insertion hole 153 defined in the cover 20, and a first snapping slot 152, which is defined in the outer side frame (such as the first side 101, the second side 102, the third side 103, and the fourth side 104 in FIG. 3 and FIG. 13) and is corresponding to the first insertion hole 153. The first snap body 151 is configured to extend through the first insertion hole 153 in the cover 20 to be snapped with the first snapping slot 152 in the outer side frame. In this way, for the package housing 1, detachable connection between the outer frame 10 and the cover 20 may be achieved through the first snap portion 15, ensuring that the power chip may be easily received into the package housing 1 due to the detachable connection. Compared to the related art where bolt connection is applied, in the present disclosure, the first snap portion 15 allows the outer frame 10 and the cover 20 to be detachably connected to each other and further allows the outer frame 10 and the cover 20 to be connected to each other more firmly, and a better assembling efficiency can be achieved.

To allow the outer frame 10 and the cover 20 to be connected to each other even more firmly, a plurality of first snap portions 15 may be arranged. The plurality of first snap portions 15 may be located at the edges of combination of the heat dissipation bottom plate 30, the outer frame 10, and the cover 20, and may be spaced apart from each other and disposed on two symmetrical edges.

As shown in FIG. 15 and FIG. 16, in some embodiments, the first snap body 151 includes a cap body 1512 and a plurality of elastic snap hooks 1511 disposed on the cap body 1512. Each of the plurality of elastic snap hooks 1511 may be made of a material that has certain hardness and toughness and is capable of being elastically deformed, such as made of plastic or metal. When the first snap body 151 extends through the first insertion hole 153 in the cover 20 to be snapped with the first snapping slot 152 in the outer frame, the plurality of elastic snap hooks 1511 are configured to be snapped with the first snapping slot 152. While assembling, the plurality of elastic snap hooks 1511 may be elastically deformed and may be inserted into the first snapping slot 152. Further, when assembled in place, the plurality of elastic snap hooks 1511 are restored to original shapes to be snapped with the first snapping slot 152. The first snap body 151 has low cost, can be assembled easily, has high reliability, and may not damage appearance of the component.

The cap body 1512 may be a cylindrical structure or a prismatic structure, having a radial size greater than a radial size of the first insertion hole 153. In this way, the cap body 1512 may remain at an outer surface of the cover 20 during snapping and assist the plurality of elastic snap hooks 1511 in preventing the cover 20 from detaching from the outer frame 10. In addition, the cap body 1512 has a simple structure, may be processed easily, and has a low production cost.

In some embodiments, one or more elastic snap hooks 1511 may be arranged. Although connection strength may be increased as the number of elastic snap hooks 1511 increases, an excessive number of elastic snap hooks 1511 may increase the manufacturing cost and a risk of breakage. Therefore, it is recommended that four elastic snap hooks are arranged, which is the most economical and reliable arrangement. The four elastic snap hooks 1511 are arranged to be evenly distributed to surround a specified axis. The specified axis is a straight line coinciding with a central axis of the cap body 1512. Therefore, the four elastic snap hooks 1511, which are evenly distributed, ensure that the first snap body 151 to be connected to the first snapping slot 152 safely and reliably.

In some embodiments, the first snap body 151 further includes a reinforcing post 1513 disposed between the cap body 1512 and the plurality of elastic snap hooks 1511. The reinforcing post 1513 is disposed between and connected to the plurality of elastic snap hooks 1511. The reinforcing post 1513 reduces a risk of the elastic snap hooks 1511 being fractured during deformation. The reinforcing post 1513 may be cylindrical or prismatic in shape and is configured to be connected to each of the plurality of elastic snap hooks 1511. For the reinforcing post 1513, an end of the reinforcing post 1513 away from the cap body 1512 is received in the first insertion hole 153 when the first snap body 151 extends through the first insertion hole 153 to be further snapped with the first snapping slot 152. In this way, the elastic snap hooks 1511 may have sufficient space for deformation, further reducing the risk of the elastic snap hooks 1511 being broken during deformation. To be noted that the first snap body 151, which includes the cap body 1512, the elastic snap hook 1511, and the reinforcing post 1513, may be configured as a one-piece and integral structure and may be preferably made of plastic.

As shown in FIG. 16, the elastic snap hook 1511 includes a rod 1511c connected to the cap body 1512 and a snap tab 1511b disposed on an end of the rod 1511c away from the cap body 1512. The snap tab 1511b includes a first snapping plane 1511a facing towards the cap body 1512 and configured to snap with the first snapping slot 152. When the first snap body 151 is gradually inserted into the first snapping slot 152, the rod 1511c is required to be elastically deformed to allow the end having the snap tab 1511b to approach the specified axis to ensure the end of the rod 1511c having the snap tab 1511b to be inserted into the first snapping slot 152 smoothly. When the first snap body 151 is inserted into the first snapping slot 152, reaching a specified position, the rod 1511c may be restored by its own elasticity and drive the end having the snap tab 1511b to move away from the specified axis until the first snapping plane 1511a being snapped with the first snapping slot 152. However, in order to reduce operational difficulties, the elastic snap hook 1511 may further include a guiding tilted face 1511d, which is disposed on the rod 1511c and on the snap tab 1511b and is connected to the first snapping plane 1511a. A normal line of the first snapping plane 1511a extends in a direction away from the cap body 1512 and the specified axis. When the first snap body 151 is inserted into the first snapping slot 152, the guiding tilted face 1511d allows the rod 1511c to be elastically deformed and drives the end of the rod having the snap tab 1511b to move approaching the specified axis, ensuring the end of the rod 1511c having the snap tab 1511b to be inserted into the first snapping slot 152 smoothly.

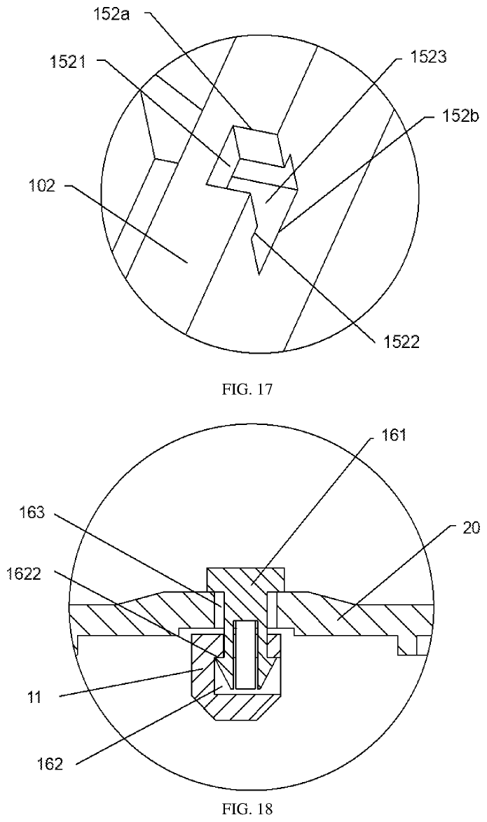

As shown in FIG. 15, the first snapping slot 152 is defined in the outer side frame. When the first snapping slot is defined at a thin portion of the outer side frame, the first snapping slot 152 may be a through hole. When the first snapping slot is defined at a thick portion of the outer side frame, the first snapping slot 152 may be a stepped recess. As shown in FIG. 17, the first snapping slot 152 is a stepped recess and includes a narrow zone 1521, a wide zone 1523 (see FIG. 15), and a second snapping plane 1522. The wide zone 1523 is connected to the narrow zone 1521 and is disposed further away from the cover 20 than the narrow zone 1521. The second snapping plane 1522 is formed at an intersection between the narrow zone 1521 and the wide zone 1523. The narrow zone 1521 has a first opening 152a that allows the first snap body 151 to pass through, such that the first snap body 151 can be inserted into the first snapping slot 152 and can further be snapped with the first snapping slot 152 and more particularly snapped with the second snapping plane 1522.

While performing the assembling, the guiding tilted face 1511d of the first snap body 151 contacts the narrow zone 1521 and causes the plurality of elastic snap hooks 1511 to be deformed and to approach towards each other, such that the end having the snap tab 1511b may smoothly pass through the narrow zone 1521 to be inserted into the wide zone 1523. After the snap tab 1511b of each elastic snap hook 1511 passes through the narrow zone 1521 to be inserted into the wide zone 1523, each rod 1511c is restored to the original shape due to the elastic force and causes the end of each elastic snap hook 1511 having the snap tab 1511b to expand, such that the first snapping plane 1511a of each snap tab 1511b contacts and snaps with the second snapping plane 1522 of the first snapping slot 152.

In some embodiments, the first snapping slot 152 further includes a second opening 152b, which is perpendicular to the first opening 152a and exposes the narrow zone 1521 and the wide zone 1523. For example, the face that defines the first opening 152a is perpendicular to the face that defines the second opening 152b. This second opening 152b is suitable for manufacturing needs, effectively reducing the difficulty and cost of manufacturing the first snapping slot 152.

Exemplarily, the first insertion hole 153 in the cover 20 is defined to allow the first snap body 151 to pass through the cover 20 to be further inserted into the first snapping slot 152, such that snapping between the cover 20 and the outer frame 10 is achieved. The first insertion hole 153 may be a through hole or a counterbore. In an embodiment, the first insertion hole 153 is the counterbore, allowing the cap body 1512 of the first snap body 151 to be entirely received in the counterbore, improving the aesthetics of the cover 20.

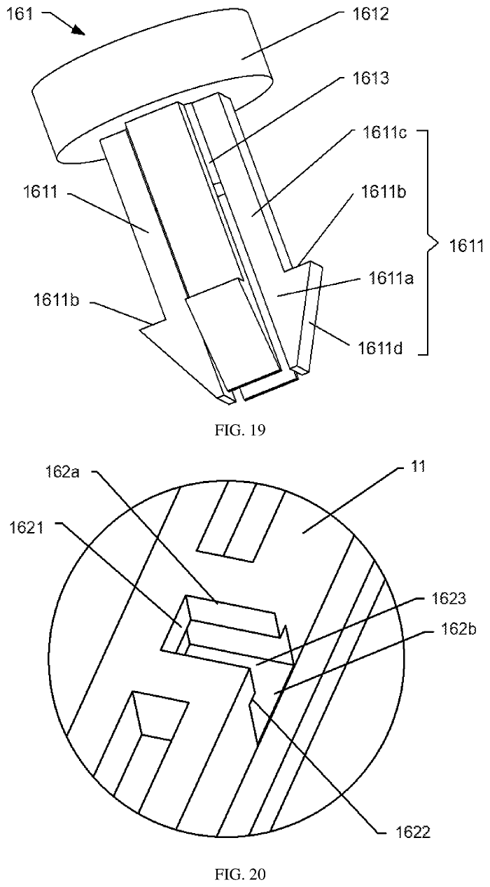

As shown in FIG. 13 and FIG. 14, the outer frame 10 further includes the connecting member 11 (see FIG. 13 for details). The connecting member 11 is configured to define sub-regions for mounting power chips, and each sub-region is capable of receiving one power chip. As shown in FIG. 13 and FIG. 19, the package housing 1 further includes a second snap portion 16. The second snap portion 16 includes a second snap body 161, a second insertion hole 163 defined in the cover 20, and a second snapping slot 162. The second snapping slot 162 is defined in the outer side frame and corresponds to the second insertion hole 163. The second snap body 161 is configured to pass through the second insertion hole 163 in the cover 20 to be further snapped with the second snapping slot 162 in the connecting member 11. In this way, in the package housing 1, detachable connection between the outer frame 10 and the cover 20 can be achieved through the second snap portion 16, such that the power chip may be easily received into the package housing 1 due to the detachable connection. Compared to the related art where bolt connection is applied, in the present disclosure, the second snap portion 16 allows the outer frame 10 and the cover 20 to be detachably connected to each other and further allows the outer frame 10 and the cover 20 to be connected to each other more firmly, and a better assembling efficiency can be achieved.

To further improve strength of the snapping connection, a plurality of second snap portions 16 are preferably arranged. The plurality of second snap portions 16 are spaced apart from each other and are arranged on the connecting member 11. Compared to the related art where bolt connection is applied, in the present disclosure, the second snap portions 16 allow the outer frame 10 and the cover 20 to be detachably connected to each other and further allow the outer frame 10 and the cover 20 to be connected to each other more firmly, and a better assembling efficiency can be achieved.

As shown in FIG. 18 and FIG. 19, in some embodiments, the second snap body 161 includes a cap body 1612 and a plurality of elastic snap hooks 1611 arranged on the cap body 1612. Each of the plurality of elastic snap hooks 1611 may be made of a material that has certain hardness and toughness and is capable of being elastically deformed, such as made of plastic or metal. When the second snap body 161 extends through the second insertion hole 163 in the cover 20 to be snapped with the second snapping slot 162 in the outer side frame, the plurality of elastic snap hooks 1611 are configured to be snapped with the second snapping slot 162. While assembling, the plurality of elastic snap hooks 1611 may be elastically deformed and may be inserted into the second snapping slot 62. Further, when assembled in place, the plurality of elastic snap hooks 1611 are restored to original shapes to be snapped with the second snapping slot 162. The second snap body 161 has low cost, can be assembled easily, has high reliability, and may not damage appearance of the component. A structure and an assembly process of the second snap body 161 may be the same as those of the first snap body 151. While performing assembling, the first snap body 151 and the second snap body 161 may be replaced with each other, such that a production cycle and production costs may be further reduced.

The cap body 1612 may be a cylindrical structure or a prismatic structure, having a radial size greater than a radial size of the second insertion hole 163. In this way, the cap body 1512 may remain at an outer surface of the cover 20 during snapping and assist the plurality of elastic snap hooks 1611 in preventing the cover 20 from detaching from the outer frame 10. In addition, the cap body 1612 has a simple structure, may be processed easily, and has a low production cost.

In some embodiments, one or more elastic snap hooks 1611 may be arranged. Although connection strength may be increased as the number of elastic snap hooks 1611 increases, an excessive number of elastic snap hooks 1611 may increase the manufacturing cost and a risk of breakage. Therefore, it is recommended that four elastic snap hooks are arranged, which is the most economical and reliable arrangement. The four elastic snap hooks 1611 are arranged to be evenly distributed to surround a specified axis. The specified axis is a straight line coinciding with a central axis of the cap body 1612. Therefore, the four elastic snap hooks 1611, which are evenly distributed, ensure that the second snap body 161 to be connected to the second snapping slot 162 safely and reliably.

In some embodiments, the second snap body 161 further includes a reinforcing post 1613 disposed between the cap body 1612 and the plurality of elastic snap hooks 1611. The reinforcing post 1613 is disposed between and connected to the plurality of elastic snap hooks 1611. The reinforcing post 1613 reduces a risk of the elastic snap hooks 1611 being fractured during deformation. The reinforcing post 1613 may be cylindrical or prismatic in shape and is configured to be connected to each of the plurality of elastic snap hooks 1611. For the reinforcing post 1613, an end of the reinforcing post 1613 away from the cap body 1612 is received in the second insertion hole 163 when the second snap body 161 extends through the second insertion hole 163 to be further snapped with the second snapping slot 162. In this way, the elastic snap hooks 1611 may have sufficient space for deformation, further reducing the risk of the elastic snap hooks 1611 being broken during deformation. To be noted that the second snap body 161, which includes the cap body 1612, the elastic snap hook 1611, and the reinforcing post 1613, may be configured as a one-piece and integral structure and may be preferably made of plastic.

As shown in FIG. 19, the elastic snap hook 1611 includes a rod 1611c connected to the cap body 1612 and a snap tab 1611b disposed on an end of the rod 1611c away from the cap body 1612. The snap tab 1611b includes a first snapping plane 1611a facing towards the cap body 1612 and configured to snap with the second snapping slot 162. When the second snap body 161 is gradually inserted into the second snapping slot 162, the rod 1611c is required to be elastically deformed to allow the end having the snap tab 1611b to approach the specified axis to ensure the end of the rod 1611c having the snap tab 1611b to be inserted into the second snapping slot 162 smoothly. When the second snap body 161 is inserted into the second snapping slot 162, reaching a specified position, the rod 1611c may be restored by its own elasticity and drive the end having the snap tab 1611b to move away from the specified axis until the second snapping plane 1611a being snapped with the second snapping slot 162. However, in order to reduce operational difficulties, the elastic snap hook 1611 may further include a guiding tilted face 1611d, which is disposed on the rod 1611c and on the snap tab 1611b and is connected to the second snapping plane 1611a. A normal line of the second snapping plane 1611a extends in a direction away from the cap body 1612 and the specified axis. When the second snap body 161 is inserted into the second snapping slot 162, the guiding tilted face 1611d allows the rod 1611c to be elastically deformed and drives the end of the rod having the snap tab 1611b to move approaching the specified axis, ensuring the end of the rod 1611c having the snap tab 1611b to be inserted into the second snapping slot 162 smoothly.

A structure of the second snap portion 16 is the same as the structure of the first snap portion 15, such that the first snap body 151 and/or the second snap body 161 may be assembled easily, further reducing the production cycle and production costs.

As shown in FIG. 20, the second snapping slot 162 is defined in the connecting member 11. When the second snapping slot 162 is defined at a thin portion of the connecting member 11, the second snapping slot 162 may be a through hole. When the second snapping slot is defined at a thick portion of the connecting member 11, the second snapping slot 162 may be a stepped recess. As shown in FIG. 20, the second snapping slot 162 is a stepped recess and includes a narrow zone 1621, a wide zone 1623, and a second snapping plane 1622 (as shown in FIG. 19). The wide zone 1623 is connected to the narrow zone 1621 and is disposed further away from the cover 20 than the narrow zone 1621. The second snapping plane 1622 is formed at an intersection between the narrow zone 1621 and the wide zone 1623. The narrow zone 1621 has a first opening 162a that allows the second snap body 161 to pass through, such that the second snap body 161 can be inserted into the second snapping slot 162 and can further be snapped with the second snapping slot 162, more particularly snapped with the second snapping plane 1622. While performing the assembling, the guiding tilted face 1611d of the second snap body 161 contacts the narrow zone 1621 and causes the plurality of elastic snap hooks 1611 to be deformed and to approach towards each other, such that the end having the snap tab 1611d may smoothly pass through the narrow zone 1621 to be inserted into the wide zone 1623. After the snap tab 1611d of each elastic snap hook 1611 passes through the narrow zone 1621 to be inserted into the wide zone 1623, each rod 1611c is restored to the original shape due to the elastic force and causes the end of each elastic snap hook 1611 having the snap tab 1611b to expand, such that the first snapping plane 1611a of each snap tab 1611b contacts and snaps with the second snapping plane 1622 of the second snapping slot 162.

In some embodiments, the second snapping slot 162 further includes a second opening 162b, which is perpendicular to the first opening 162a and exposes the narrow zone 1621 and the wide zone 1623. For example, the face that defines the first opening 162a is perpendicular to the face that defines the second opening 162b. The second opening 162b is suitable for manufacturing needs, effectively reducing the difficulty and cost of manufacturing the second snapping slot 162.

Exemplarily, the second insertion hole 163 in the cover 20 is defined to allow the second snap body 161 to pass through the cover 20 to be further inserted into the second snapping slot 162, such that snapping between the cover 20 and the outer frame 10 is achieved. A structure of the second insertion hole 163 is the same as the structure of the first insertion hole 153, and that is, the second insertion hole 163 may be a through hole or a counterbore. In an embodiment, the second insertion hole 163 is the counterbore, allowing the cap body 1612 of the second snap body 161 to be entirely received in the counterbore, improving the aesthetics of the cover 20.

To summarize, for the package housing 1 in the above embodiments, detachable connection between the outer frame 10 and the cover 20 may be achieved through the first snap portion 15 and the second snap portion 16, ensuring that the power chip may be easily received into the package housing 1 due to the detachable connection. Compared to the related art where bolt connection is applied, in the present disclosure, the first snap portion 15 and the second snap portion 16 allow the outer frame 10 and the cover 20 to be detachably connected to each other and further allow the outer frame 10 and the cover 20 to be connected to each other more firmly, and a better assembling efficiency can be achieved.

In an embodiment, the package housing 1 includes one of the first snap portion 15 and the second snap portion 16. The detachable connection between the outer frame 10 and the cover 20 is achieved by one of the first snap portion 15 and the second snap portion 16. In this way, higher connection strength can be achieved, and a higher assembling efficiency can be achieved.

In addition, in the present disclosure, unless otherwise expressly specified and limited, terms “coupled”, “connected (electrically connected)”, “laminated”, and so on, shall be understood in a broad sense. For example, the connection may be fixed connection, detachable connection, various components being configured as a one-piece structure, direct connection, indirect connection through an intermediate medium, two components being internally connected with each other, or an interaction between two components. Any ordinary skilled person in the art shall understand the specific meaning of the above terms in the context of the present disclosure case-by-case.

Finally, it should be noted that the above embodiments are only used to illustrate the technical solutions of the present disclosure, but do not limit the present disclosure. Although the present disclosure is described in detail by referring to the above embodiments, it shall be understood by any ordinary skilled person in the art that, the technical solutions in the above embodiments can be modified, some or all of the technical features can be replaced with equivalent ones. These modifications or replacements shall not make the essence of the corresponding technical solutions depart away from the scope of the present disclosure.

What is claimed is:

1. A package housing, comprising:
an outer frame;
a cover, connected to a side of the outer frame;
a heat dissipation bottom plate, connected to the other side of the outer frame, wherein the heat dissipation bottom plate, the outer frame, and cover cooperatively define a receiving space, the outer frame has a connecting member disposed inside the receiving space, the connecting member is disposed between the heat dissipation bottom plate and the cover; and
a fixing structure, configured to connect the connecting member to the cover, wherein a part of the fixing structure located in the receiving space has an autographic projection on the connecting member, and the entire autographic projection locates on a surface of the connecting member near the cover.

2. The package housing according to claim 1, wherein, the cover defines a through hole, and the fixing structure comprises:
a fixing portion, connected to a side of the connecting member near the cover, wherein the fixing portion extends through the through hole, a part of the fixing portion located in the receiving space has an autographic projection on the connecting member, and the entire autographic projection locates on the surface of the connecting member near the cover; and
a deformation portion, connected to the fixing portion and disposed on a side of the cover away from the connecting member, wherein the deformation portion and the connecting member cooperatively clamp and fix the cover.

3. The package housing according to claim 2, wherein,
the fixing portion comprises a first fixing plate and a second fixing plate opposite to the first fixing plate, an end of the first fixing plate is connected to an end of the second fixing plate, the other end of the first fixing plate and the other end of the second fixing plate are connected to the connecting member and are spaced apart from each other;
the deformation portion comprises a first deformation sub-portion and a second deformation sub-portion, the first deformation sub-portion is connected to the first fixing plate and extends towards the cover to abut against the cover, the first deformation sub-portion extends away from the first fixing plate;
the second deformation sub-portion is connected to the second fixing plate and extends towards the cover to abut against the cover, and the second deformation sub-portion extends away from the first fixing plate.

4. The package housing according to claim 3, wherein,
the first fixing plate defines a first reservation hole at a position corresponding to the first deformation sub-portion, the second fixing plate defines a second reservation hole at a position corresponding to the second deformation sub-portion;
the first deformation sub-portion is configured to bend elastically towards the first fixing plate to be received in the first reservation hole, the second deformation sub-portion is configured to bend elastically towards the second fixing plate to be received in the second reservation hole.

5. The package housing according to claim 2, wherein,
the deformation portion comprises a plurality of deformation sub-portions, each of the plurality of deformation sub-portions is connected to the fixing portion and extends towards the cover to abut against the cover; and each of the plurality of deformation sub-portions extends away from the fixing portion.

6. The package housing according to claim 1, wherein, the cover defines a through hole, and the fixing structure comprises:
a first snap portion, connected to the side of the connecting member near the cover, wherein the first snap portion extends through the through hole, a part of the first snap portion disposed inside the receiving space has an autographic projection on the connecting member, and the autographic projection locates on the surface of the connecting member near the cover; and
a second snap portion, snapped with the first snap portion and disposed on a side of the cover away from the connecting member, wherein the second snap portion and the connecting member cooperatively clamp and fix the cover.

7. The package housing according to claim 6, wherein,
the first snap portion comprises a flange portion and a rod portion, an end of the rod portion is connected to the connecting member, and the other end of the rod portion is connected to a middle of the flange portion, a part of the rod portion located inside the receiving space has an autographic projection on the connecting member, and the autographic projection locates on the surface of the connecting member near the cover;
the second snap portion comprises a mounting portion and a plurality of elastic portions, the mounting portion is disposed on a side of the cover away from the connecting member, the plurality of elastic portions are arranged on the mounting portion and are disposed around an outer circumference of the rod portion, an end of each of the plurality of elastic portions is connected to the mounting portion and extends towards the through hole to abut against the flange portion, and each of the plurality of elastic portions extends away from the cover.

8. The package housing according to claim 7, wherein,
the first snap portion further comprises a first extension portion and a second extension portion, the first extension portion extends from a circumference of the flange portion towards the rod portion, the second extension portion extends from a circumferential side of the first extension portion near the rod portion away from the cover, the first extension portion, the second extension portion, the flange portion, and the rod portion cooperatively define an embedding slot; and
each of the plurality of elastic portions comprises an embedding portion and a connecting portion, an end of the connecting portion is connected to the mounting portion and is extending to approach the through hole to abut against the flange portion and the first extension portion, the connecting portion is extending away from the cover, the embedding portion is connected to an end of the connecting portion away from the cover and is received in the embedding slot to be snapped with the first extension portion and the second extension portion.

9. The package housing according to claim 1, wherein the outer frame has a plurality of connecting members disposed inside the receiving space, the plurality of connecting members are spaced apart from each other to divide the receiving space into a plurality of receiving regions.

10. The package housing according to claim 1, wherein the outer frame comprises a first side, a second side, a third side, and a fourth side; the first side, the second side, the third side, and the fourth side are arranged in sequence and are connected to each other end-to-end; an end of the connecting member is connected to the first side, and the other end of the connecting member is connected to the third side.

11. The package housing according to claim 10, wherein the outer frame has a first snap member, a second snap member, a third snap member, and a fourth snap member, the first snap member is disposed near connection between the first side and the second side;
the second snap member is disposed near connection between the second side and the third side;
the third snap member is disposed near connection between the third side and the fourth side;
the fourth snap member is disposed near connection between the fourth side and the first side; and
each of the first snap member, the second snap member, the third snap member, and the fourth snap member is snapped with the cover.

12. A package housing, comprising:
an outer frame;
a cover, connected to a side of the outer frame, wherein the outer frame and cover cooperatively define a receiving space; and
a fixing structure, connected to the outer frame and the cover, wherein a part of the fixing structure located on a side of the cover facing towards the outer frame has an autographic projection on the outer frame, and the entire autographic projection locates on a surface of the outer frame near the cover.

13. The package housing according to claim 12, wherein,
the outer frame comprises a first side, a second side, a third side, and a fourth side, the first side, the second side, the third side, and the fourth side are arranged in sequence and are connected to each other end-to-end, the first side is opposite to the third side, and the second side is opposite to the fourth side; and
the fixing structure is disposed on each of a side of the first side facing towards the cover and a side of the third side facing towards the cover, the part of the fixing structure located on the side of the cover facing the outer frame has the autographic projection on the outer frame, and the entire autographic projection of the fixing structure disposed on the first side locates on a surface of the first side near the cover, the entire autographic projection of the fixing structure disposed on the third side locates on a surface of the third side near the cover; or
the fixing structure is disposed on each of a side of the second side facing towards the cover and a side of the fourth side facing towards the cover, the part of the fixing structure located on the side of the cover facing the outer frame has the autographic projection on the outer frame, and the entire autographic projection of the fixing structure disposed on the second side locates on a surface of the second side near the cover, the entire autographic projection of the fixing structure disposed on the fourth side locates on a surface of the fourth side near the cover.

14. The package housing according to claim 12, wherein, the cover defines a through hole, and the fixing structure comprises:
a fixing portion, connected to the side of the outer frame near the cover, wherein the fixing portion extends through the through hole, a part of the fixing portion located on the side of the cover facing the outer frame has an autographic projection on the outer frame, and the entire autographic projection locates on the surface of the outer frame near the cover; and
a deformation portion, connected to the fixing portion and located on the side of the cover away from the outer frame, wherein the deformation portion and the outer frame cooperatively clamp and fix the cover.

15. The package housing according to claim 14, wherein,
the fixing portion comprises a first fixing plate and a second fixing plate opposite to the first fixing plate, an end of the first fixing plate is connected to an end of the second fixing plate, the other end of the first fixing plate and the other end of the second fixing plate are connected to the outer frame and are spaced apart from each other;
the deformation portion comprises a first deformation sub-portion and a second deformation sub-portion, the first deformation sub-portion is connected to the first fixing plate and is extending towards the cover to abut against the cover, and the first deformation sub-portion is extending away from the first fixing plate; and
the second deformation sub-portion is connected to the second fixing plate and is extending towards the cover to abut against the cover, and the second deformation sub-portion is extending away from the first fixing plate.

16. The package housing according to claim 15, wherein, the first fixing plate defines a first reservation hole at a position corresponding to the first deformation sub-portion, the second fixing plate defines a second reservation hole at a position corresponding to the second deformation sub-portion, the first deformation sub-portion is configured to be elastically bent towards the first fixing plate and is capable of being received in the first reservation hole, the second deformation sub-portion is configured to be elastically bent towards the second fixing plate and is capable of being received in the second reservation hole.

17. The package housing according to claim 14, wherein the deformation portion comprises a plurality of deformation sub-portions, each of the plurality of deformation sub-portions is connected to the fixing portion and is extending towards the cover to abut against the cover, and each of the plurality of deformation sub-portions is extending away from the fixing portion.

18. The package housing according to claim 12, wherein the cover defines a through hole, and the fixing structure comprises:
a first snap portion, connected to the side of the outer frame near the cover and extending through the through hole, wherein a part of the first snap portion arranged on the side of the cover facing towards the outer frame has an autographic projection on the outer frame, and the autographic projection locates on the surface of the outer frame near the cover; and
a second snap portion, snapped with the first snap portion and disposed at the side of the cover away from the outer frame, wherein the second snap portion and the outer frame cooperatively clamp and fix the cover.

19. The package housing according to claim 18, wherein,
the first snap portion comprises a flange portion and a rod portion, an end of the rod portion is connected to the outer frame, and the other end of the rod portion is connected to a middle of the flange portion, a part of the rod portion arranged on the side of the cover facing towards the outer frame has an autographic projection on the outer frame, and the autographic projection locates on the surface of the outer frame near the cover; and
the second snap portion comprises a mounting portion and a plurality of elastic portions, the mounting portion is disposed on the side of the cover away from the outer frame, the plurality of elastic portions are arranged on the mounting portion and are disposed around an outer circumference of the rod portion, an end of each of the plurality of elastic portions is connected to the mounting portion and is extending towards the through hole to abut against the flange portion, and each of the plurality of elastic portions is extending away from the cover.

20. The package housing according to claim 19, wherein,
the first snap portion further comprises a first extension portion and a second extension portion, the first extension portion extends from a circumference of the flange portion towards the rod portion, the second extension portion extends from a circumferential side of the first extension portion near the rod portion away from the cover, the first extension portion, the second extension portion, the flange portion, and the rod portion cooperatively define an embedding slot; and
each of the plurality of elastic portions comprises an embedding portion and a connecting portion, an end of the connecting portion is connected to the mounting portion and is extending to approach the through hole to abut against the flange portion and the first extension portion, the connecting portion is extending away from the cover, the embedding portion is connected to an end of the connecting portion away from the cover and is received in the embedding slot, the embedding portion is snapped with the first extension portion and the second extension portion.
